(19) United States
(12) Patent Application Publication
(10) Pub. No.: US 2022/0344953 A1
(43) Pub. Date: Oct. 27, 2022

(54) ChargerSafe

(71) Applicant: CHARGERSAFE LLC, Brookeside, NJ (US)

(72) Inventor: Kate Harner, Brookside, NJ (US)

(21) Appl. No.: 17/604,593

(22) PCT Filed: May 3, 2020
(86) PCT No.: PCT/US2020/031232

§ 371 Date: Oct. 18, 2021

Related U.S. Application Data
(60) Provisional application No. 62/845,563, filed on May 9, 2019.

(51) Int. Cl. H02J 7/00; A47B 81/00; H05K 7/20; H05K 5/02

(52) U.S. Cl. CPC H02J 7/0044; A47B 81/00; H05K 7/20127; H05K 5/0221; H05K 5/0247

(57) ABSTRACT

The technical field to which the invention pertains is securing objects from unauthorized use by children at home. ChargerSafe is a child-proofing apparatus to be used by parents to limit children-s screen time. ChargerSafe is a vented metal box with a combination, biometric, or digital lock and round openings with protective grommets in the sides that allow the user to thread charging cables from external electrical outlets to the inside where electronic devices (phones, tablets, chromebooks) are placed, plugged in, and charged with the door locked. Removable dividers are added inside to prevent devices from stacking. The principal use of the invention is locking devices up as a solution to the problem of screen time management at home. ChargerSafe combines the functions of securely storing electronic devices to prevent unauthorized use by children, while charging these devices at the same time.

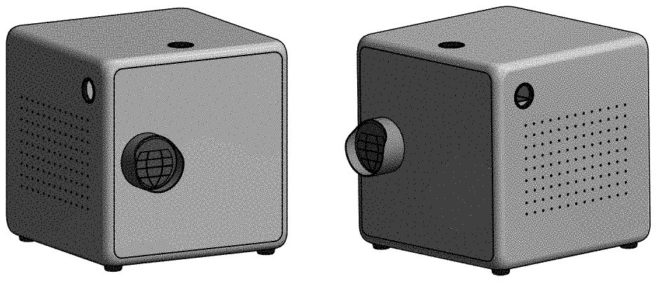

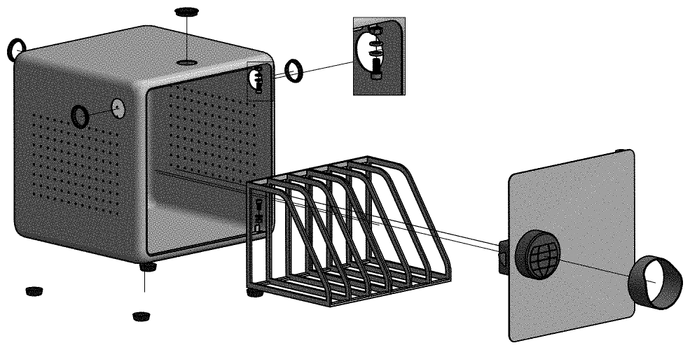

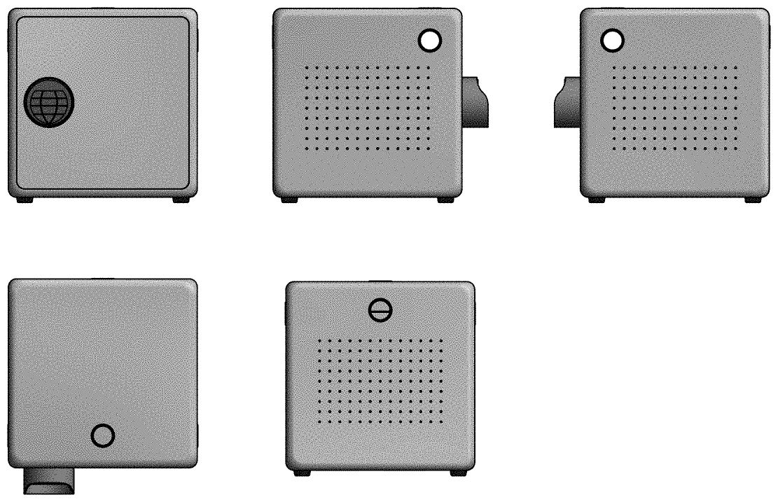

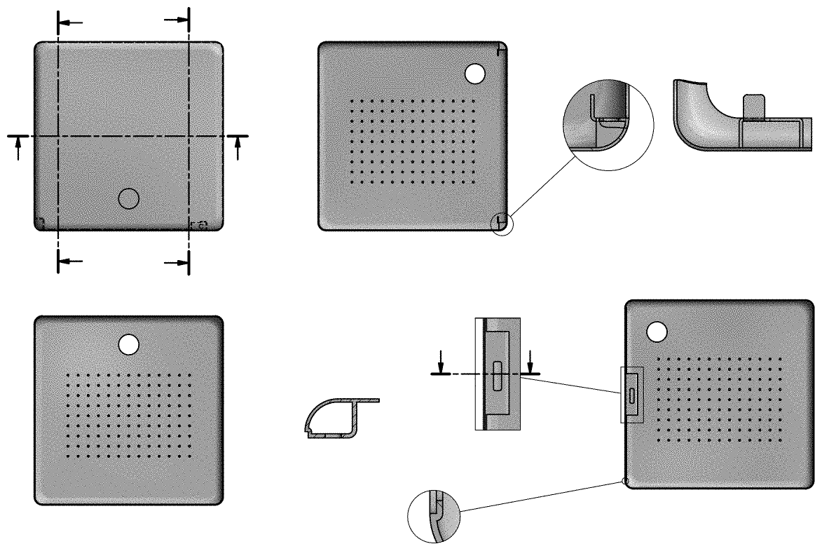

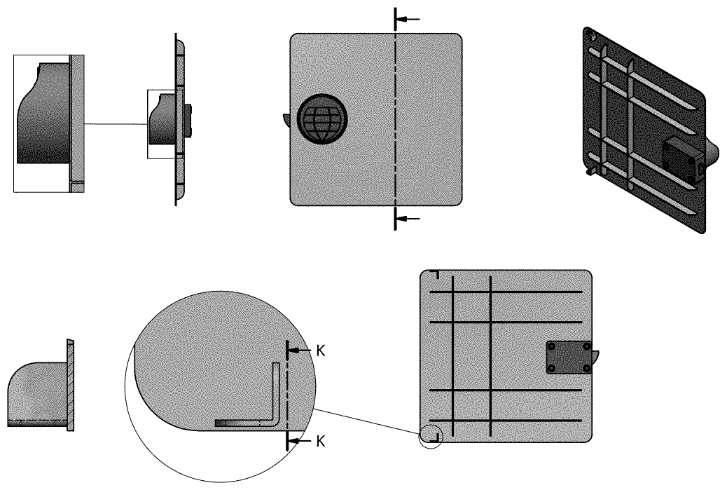

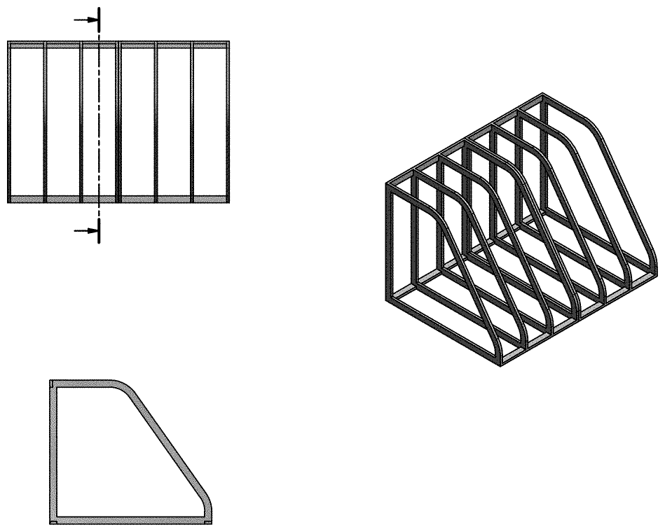

### TECHNICAL FIELD

The present invention relates to parenting around technology, in particular making a home environment safer for children. ChargerSafe is meant to be used by parents and other caregivers at home to control the amount of time children spend on electronic devices.

ChargerSafe is a vented metal box with a lock and round openings for the purpose of threading charging cables through from external electrical outlets; a charging station can also be placed inside to charge a variety of electronic devices while keeping them inaccessible to children. ChargerSafe combines the functions of securely storing electronic devices to prevent unauthorized use by children at home, while giving users the ability to charge these devices at the same time.

ChargerSafe user will unlock the door, place a device inside, plug it in, and lock the door.

Certain embodiments of the ChargerSafe include, but are not limited to:
ChargerSafe lock can be a combination lock (the type typically used in safes to secure valuables), biometric fingerprint lock, or digital Bluetooth-enabled lock operated from a specially designed smartphone app. A lock could be either battery-operated or wired, as well as a USB-powered device in itself. An override key should be available for malfunctions or emergencies.
Pre-drilled holes with protective grommets could be made in the back, the top and the sides of the ChargerSafe for threading charging cables through and/or placing a charging dock inside.
Timer feature on the lock can be made available showing a countdown to the time the lock automatically opens.
Removable dividers are added inside to prevent devices from stacking and to accommodate devices of various sizes (laptops, tablets, phones, etc). Dividers could be made of metal or plastic.
A USB charging station can be built in, although ChargerSafe is designed to be used with the charging cables the user already has.
ChargerSafe can be made in small, medium, or large size depending on the number and size of devices to be locked.
The corners of ChargerSafe will have rounded edges.
ChargerSafe could be made with the use of various materials, including metal and plastic.
Sides of the ChargerSafe should be vented to prevent the devices from overheating.
ChargerSafe can come in a variety of colors and include external designs customized for the user.

### BACKGROUND ART

Although large commercial smart phone lockable charging stations had been used in public spaces (malls, airports, colleges, conferences, events, etc.), and small personal security cases had been used by individuals, these all serve to protect electronic devices from theft in public places. Charging devices at home is currently done without locking them up. Present invention seeks to address the need to protect children from using electronic devices excessively, as there is an increasing need for screen time management at home.

### UNFULFILLED NEED

Screen time addiction among kids and teens has reached epidemic proportions, and it can be argued that screen time management is the number one concern of parents today. Neuroscience has proven that the dopamine release mechanism in the brain reacts the same way to the use of electronic devices, as the brain of an alcoholic reacts to a drink, heroin addict to a dose, or gambling addict to a slot machine. When screen time is excessive, it negatively affects all areas of children's lives. The problem is fairly recent (iPhone was introduced in 2007, iPad in 2010), but the effects on the children are acute and became very apparent since the year 2011-2012, exactly when smartphones became standard. More research comes out all the time warning parents of potential harms of digital media overuse. Families of children on the disorder spectrum, particularly Attention Deficit Disorder which is biologically linked to dopamine production in the brain, can especially benefit from the use of ChargerSafe.

### SERIOUS NATURE OF THE PROBLEM

Numerous scientific studies and parenting experts have outlined the many dangers of unrestricted technology use by children, the list is long and extremely disturbing:
Abnormal brain development (Adolescent Brain Cognitive Development study: https://abcdstudy.org/?s=screen-Ftime, featured in NYTimes, Fortune, CBS and other media outlets)
Increased rates of anxiety and depression in the atmosphere of toxic comparison on social media and cyber-bullying. The study found that adolescents who spend more than seven hours a day having screen time were twice as likely as those spending one hour to have been diagnosed with anxiety or depression (https://www.sciencedirect.com/science/article/pii/S2211335518301827)
Lack of social skills resulting from lack of practice in face-to-face communication (https://www.psychologytoday. com/us/blogimental-wealth/201606/screentime-and-arrested-social-development)
Obesity (National Institute of Health: https://www.ncbi.nlin.nih.gov/pmc/articles/PMC5769928)
Sleep deprivation (National Sleep Foundation: https://www.sleepfoundation.org/articles/keep-tots-away-tech-better-sleep). Children addicted to technology keep their phones by their bed checking them in the middle of the night, or, if forbidden to do so by parents, are known to sneak downstairs to retrieve their phone when parents are sleeping.
Exposure to pornography and online predators. Children develop unhealthy view of sex, inappropriate photos stay online forever and can ruin their education and career prospects, or even land them with a sex offender record. Online predators use social media and game chats to lure children.
Reduced academic performance (Adolescent Brain Cognitive Development (ABCD) study and other research)
Shortened attention span (http://dl.motamem.org/microsoft-attention-spans-research-report.pdf)
Anger management issues and parent-child relationship damage during battles over screen time
Vision loss (https://www.chop.edu/news/health-tip/how-too-much-screen-time-affects-kids-eyes)
Increase in the rates of teen suicides (https://journals.sagepub.corn/doilfull/10.1177/2167702617723376)
May reinforce ADHD symptoms (https://jamanetwork.com/joumals/jamaiartiele-abstract/2687861)
Technology addiction. Tech executives responsible for the creation of technology understood its dangers and limited their own kids screen time (https://www.nytimes.comJ2014/09/11/fashion/steve-jobs-apple-was-a-low-tech-parent.html)
Waste of time that could be spent more productively, depriving the kids of other childhood experiences

### RESEARCH AND SOURCES

World Health Organization

https://www.who int/news-room/detail/24-04-2019-to-grow-up-healthy-children-need-to-sit-less-and-play-more

American Academy of Pediatrics current screen time recommendations (https://www.aap.orgien-us/about-the-aap/aap-press-room/Pages/American-Academy-of-Pediatrics-Armounces-New-Recornmendations-for-Childrens-Media-Use.aspx):
For children younger than 18 months, avoid use of screen media other than video-chatting.
Parents of children 18 to 24 months of age who want to introduce digital media should choose high-quality programming, and watch it with their children to help them understand what they're seeing.
For children ages 2 to 5 years, limit screen use to 1 hour per day of high-quality programs. Parents should co-view media with children to help them understand what they are seeing and apply it to the world around them.
For children ages 6 and older, place consistent limits on the time spent using media, and the types of media, and make sure media does not take the place of adequate sleep, physical activity and other behaviors essential to health.
Designate media-free times together, such as dinner or driving, as well as media-free locations at home, such as bedrooms.
Have ongoing communication about online citizenship and safety, including treating others with respect online and offline.

National Institute of Health (https://www.ncbi.nlm.nih.gov/pmc/articles/PMC6326346)

Commonsensemedia.org—leading non-profit organization providing entertainment and technology recommendations for families and schools.

Humanetech.com—Center for Humane Technology

American Psychological Association https://www.apa.org/helpcenter/digital-guidelines

Protect Young Eyes https://protectyoungeyes.com/

FamilyOnline Safety Institute: https://www.fosi.org/

Screenagersmovie.com

iGen: Why Today's Super-Connected Kids Are Growing Up Less Rebellious, More Tolerant, Less Happy--and Completely Unprepared for Adulthood--and What That Means for the Rest of Us by Jean M Twenge, PhD

Irresistible: The Rise of Addictive Technology and the Business of Keeping Us Hooked by Adam Alter

### EXISTING SOLUTIONS TO THE PROBLEM

Child's own self-control. Because children do not have a fully developed prefrontal cortex (part of the brain responsible for executive function), it is naive to expect them to limit their own screen time, especially when the industry intentionally designs technology to be addictive: https://www.commonsensemedia.org/blog/the-sneaky-science-behind-your-kids-tech-obsessions)
Passwords. Password protection is a very effective way to keep the child from unauthorized access. However, if devices like smartphones or laptops belong to the child they normally have passwords that the child knows or sets himself/herself, as it would be impractical for the parents to enter the password every time, especially in the case of smartphones used outside of the home. But placing these devices in a central charging location at home and keeping them locked up and out of sight would remove the temptation to use them.
Parental controls. The problem parental controls are solving is protecting children from the harmful content on the screen, whereas ChargerSafe solves the problem of keeping children off the screens regardless of content so they can use their time differently (sleeping, playing outside, reading, spending time with family, etc.) Setting up parental controls also requires sharing children's personal data with the provider, which compromises privacy. Very often, parental controls can be circumvented by tech-savvy kids.
Special parental control routers are designed to limit the time when the Internet is available at home. These could be difficult to set up by parents who are not trained in technology professions, disrupts parents' own Internet access, could be circumvented by children finding an alternative network, or simply staying on their screens offline. Internet time is limited, not screen time altogether.
Apps that limit screen time allow parents to set up a schedule of screen time use and have

Internet access, individual apps, or the device itself automatically shut off after a certain time. With a hot-tempered child and especially the child with neurological problems this can result in child breaking a device out or frustration. These could be time-consuming to install, may not cover every type of device, could be circumvented by tech-savvy kids, and are often a paid subscription service.

### PROBLEMS WITH EXISTING SOLUTIONS

Digital solutions do not remove the device from the children's hands, making continued use a temptation. Devices that are out in the open are easily available for children to access with or without parental permission. ChargerSafe seeks to fill the need for multiple device lockable central location at home for the purpose of screen time management and building healthy digital habits. The specific problem of protecting children from excessive technology use is fairly recent and had not been fully addressed yet. ChargerSafe can be used together with the existing parental controls solutions to help parents with screen time management at home.

### DISCLOSURE OF INVENTION

The story of the invention

ChargerSafe idea was born from a lot of parental pain our family has experienced over the years trying to protect our children, one of whom has special needs (specifically, ADHD) from harmful effects of excessive technology use on the developing brain, particularly predisposed to digital addiction. No electronic devices could be left unattended. Digital solutions did not last. Only locking the devices in a metal safe solved the problem because out child could neither break the safe nor pick the lock. This created another problem of how to charge the devices for later use. That's where the idea to drill holes to thread charging cables through came from. We have used a working prototype for years, making our screen time management effortless and greatly reducing the level of conflict in our family. I strongly believe that millions of families worldwide struggling with kids' screen time addiction could benefit from this invention, and take back control from the industry that intentionally exploits the brains of our children with addictive technology. ChargerSafe is a simple low-tech solution to a complex high-tech problem.

### ADVANTAGES OF THE INVENTION

Problem: excessive or unauthorized screen time use by children. Existing solutions are not universal, not fail-proof, can be complex and time-consuming for parents. ChargerSafe offers a solution of physically separating children from electronic devices by charging devices inside a locked box. The benefits of the invention are:
More efficient—universal across a variety of devices—existing and future
Faster—takes seconds to plug in the device and lock up the safe, less time-consuming for busy parents
Cheaper—one-time expense as opposed to a subscription service for a digital solution
More reliable—cannot be easily broken or circumvented by children
Safer—dangerous things should be locked up. Technology carries many dangers with it and should be controlled by parents for the protection of their children.
Easy to use—does not require extensive research into a variety of screen time management techniques and up-to-date knowledge of information technology
Preserves children's data privacy by being a non-digital physical product

### SUMMARY OF THE INVENTION

The present invention seeks to provide a solution to the problem of excessive screen time use by children at home by creating a physical barrier between the child and the electronic device while providing a way to charge the device at the same time.

ChargerSafe is a child-proofing apparatus to be used at home by parents to limit children's screen time exposure. It is a vented metal box with a combination or digital lock and an opening/openings in the sides for the purpose of threading charging cables through from the outside electrical outlets; a charging station can also be placed inside to charge a variety of electronic devices (smart phones, tablets, chromebooks) while keeping them inaccessible to children.

ChargerSafe combines the functions of securely storing electronic devices to prevent unauthorized use by children, while charging these devices at the same time. cl MOST IMPORTANT PREFERRED ASPECTS

Preferably, ChargerSafe has a lock on the door and one or more round openings in the sides, top, and in the back for threading charging cable/cables through. A parent would unlock the door of the safe, thread the cable plugged into the external electrical outlet to the inside of the safe through the cable access opening/openings, place a device inside the safe, plug it in, and lock the door.

### BRIEF DESCRIPTION OF DRAWINGS

There are 6 (six) pages of drawings of the ChargerSafe. The drawings depict the invention from different angles and include perspectives, exploded views, sections and cross-sections.

Page 1: 3D rendering view

Page 2: Exploding view

Page 3: Common view: front, left side, right side, top view, back view

Page 4: Case

Page 5: Door

Page 6: Divider

### BEST MODE FOR CARRYING OUT THE INVENTION

ChargerSafe is meant to be a child- and teen-proofing device that parents use at home to control the amount of time children spend on the electronic devices. Its function is to protect the children from the dangers of excessive screen time use by creating a physical barrier between the child and electronic devices, with devices securely locked up while charging. Keeping devices inaccessible and out of sight removes temptation for unauthorized use and violation of screen time rules established by the parents, reduces parent-child conflict, makes screen time management easier, and improves physical and mental health of children for better long-term outcomes in life.

### INDUSTRIAL APPLICABILITY

ChargerSafe is an invention susceptible to industrial application because it can be manufactured by existing metal products manufacturers.

### STATEMENT OF THE PRIOR ART

Prior art search in USPTO system (key words included: “charging”, “safe”, “secure”, “lock”, “device”, “power”, “electronic”, and “station”) resulted in 1254 matches. Relevant prior art patents include but may not be limited to the following patent applications: 10,076,050; 10,169,619; 9,970,217; 9,680,518; 9,680,317; 65,510,642.

### STATEMENT OF THE FEATURES FOR WHICH PROTECTION IS SOUGHT

The subject matter regarded by the applicant as the invention (ChargerSafe) is a secure metal box designed to be used by parents at home as a central location to lock electronic devices from children while charging devices at the same time. The goal of the invention is simplified screen time management to protect children from the harmful effects of excessive technology use. The invention gives parents control over the amount of screen time children are allowed to have by physically preventing unauthorized access to the devices.

The embodiments of the invention for which protection is sought are defined as follows. ChargerSafe is an apparatus comprising:

1. A secure metal box in combination with pre-drilled holes to thread charging cables through to an inside of the secure metal box.

2. The combination defined in claim 1, wherein the door of the secure metal box is locked by any type of safe lock.

3. The combination defined in claim 1, wherein protective grommets are placed over the pre-drilled holes.
The invention is novel because it is at the intersection of 3 seemingly unrelated fields: parenting, charging electronic devices and security.
The invention is non-obvious: as the problems associated with excessive screen time use by children are relatively new, a drastic approach of locking these devices as dangerous objects has not been adequately explored yet. Obvious solutions (like parental controls) only solve the problem of keeping harmful content from children's screens, not keeping children away from screens altogether.
